(19) United States
(12) Patent Application Publication
(10) Pub. No.: US 2025/0140612 A1
(43) Pub. Date: May 1, 2025

(54) METHOD FOR WAFER DICING

(71) Applicant: SILICONWARE PRECISION INDUSTRIES CO., LTD., Taichung City (TW)

(72) Inventors: Ming-Hui CHIANG, Taichung City (TW); Sheng-Yuan WANG, Taichung City (TW)

(73) Assignee: SILICONWARE PRECISION INDUSTRIES CO., LTD., Taichung City (TW)

(21) Appl. No.: 18/741,472

(22) Filed: Jun. 12, 2024

(30) Foreign Application Priority Data
Oct. 26, 2023 (TW) 112141125

(51) Int. Cl. H01L 21/78; H01L 21/268

(52) U.S. Cl. CPC H01L 21/78; H01L 21/268

(57) ABSTRACT

A wafer dicing method is provided, which includes: using a laser beam to perform a first dicing on a wafer to form a dicing lane on the wafer; using a bevel knife of a dicing machine to perform a second dicing in an inactive area of the wafer, wherein, before the second dicing, the bevel knife is raised to compensate for a thickness difference of the wafer in the inactive area and the dicing lane; and using the bevel knife to perform a third dicing in the dicing lane, wherein, during the third dicing, a wafer cut width of the second dicing is used to activate a Z-axis compensation mechanism of the dicing machine, so that the bevel knife cuts to a predetermined wafer cut width. As such, the applicable dicing lane width range of the bevel knife is increased via the precise control of the wafer cut width.

### BACKGROUND

### 1. Technical Field

The present disclosure relates to a semiconductor dicing technology, and more particularly, to a wafer dicing method.

### 2. Description of Related Art

In modern life with continuous technological advancement, electronic products play an indispensable role in people's lives. As people's demand for electronic products increases, the demand for chip packages in electronic products also increases. Therefore, how to increase the yield and production efficiency of chip packages has become an urgent problem that needs to be solved.

At present, after the wafer passes through the semiconductor integrated circuit manufacturing process, a wafer dicing step must be performed to dice the wafer into a plurality of rectangular-looking chips, and then the chips are packaged. The conventional wafer dicing method uses a diamond dicing knife to dice the wafer to separate the chips. However, dicing the wafer with a diamond dicing knife often causes stress to be concentrated on the active surface of the wafer, thereby resulting in back side chipping of the wafer. In particular, the dielectric layer of a low-k wafer is more fragile than a conventional wafer dielectric layer and is less able to withstand stress. In addition, it is known that the corners of low-k chips are prone to delamination from the encapsulant material during packaging.

For this reason, bevel knives are commonly used in advanced packaging processes to solve the stress problem of chip packages. However, due to the problem of controlling the wafer cut width with the bevel knife, there is a restriction on the width of the dicing lane to be greater than 180 micrometers (μm). As wafer fabs continue to shrink the dicing lane width for advanced packaging processes, the use of bevel knives is restricted, thereby causing the disadvantage of difficulty in dicing.

### SUMMARY

In order to solve the above problems, the present disclosure provides a wafer dicing method, which comprises: using a laser beam to perform a first dicing on a wafer to form a dicing lane on the wafer; using a bevel knife of a dicing machine to perform a second dicing in an inactive area of the wafer, wherein, before the second dicing, the bevel knife is raised to a preset height to compensate for a thickness difference of the wafer in the inactive area and the dicing lane; obtaining a wafer cut width of the second dicing via a feedback of the dicing machine; and using the bevel knife to perform a third dicing on a bottom surface of the dicing lane, wherein, during the third dicing, the wafer cut width of the second dicing is used to activate a compensation mechanism of the dicing machine, so that the bevel knife cuts to a predetermined wafer cut width.

In the present disclosure, the dicing knife is first raised and cut on the inactive area of the edge of the wafer to eliminate the thickness difference between the pre-dicing position and the third dicing position. Subsequently, the pre-dicing cut width is used to activate the Z-axis compensation mechanism of the dicing machine, so that the knife width can be accurately controlled by the knife axis when dicing the actual object, and the applicable dicing lane width range of the bevel knife can be increased via precise control of the wafer cut width, so as to solve the conventional problem of the wafer cut width being difficult to control due to the continuous shrinking of the dicing lane width, and to overcome the problem of wafer cut width errors caused by various variations.

### BRIEF DESCRIPTION OF THE DRAWINGS

FIG. 1A and FIG. 1B are respectively a top view and a cross-sectional view of a wafer before dicing according to the present disclosure.

FIG. 2A and FIG. 2B are respectively a top view and a cross-sectional view illustrating a first dicing according to a wafer dicing method of the present disclosure.

FIG. 3A and FIG. 3B are respectively a top view and a cross-sectional view illustrating a second dicing according to the wafer dicing method of the present disclosure.

FIG. 4A and FIG. 4B are respectively a top view and a cross-sectional view illustrating a third dicing according to the wafer dicing method of the present disclosure.

FIG. 5A and FIG. 5B are respectively a top view and a cross-sectional view illustrating a fourth dicing according to the wafer dicing method of the present disclosure.

### DETAILED DESCRIPTION

The following describes the implementation of the present disclosure with examples. Those skilled in the art can easily understand other advantages and effects of the present disclosure from the contents disclosed in this specification.

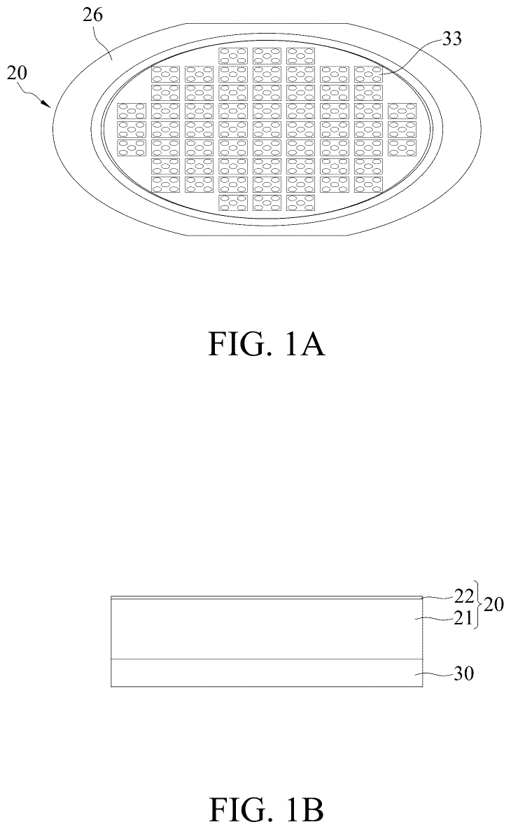

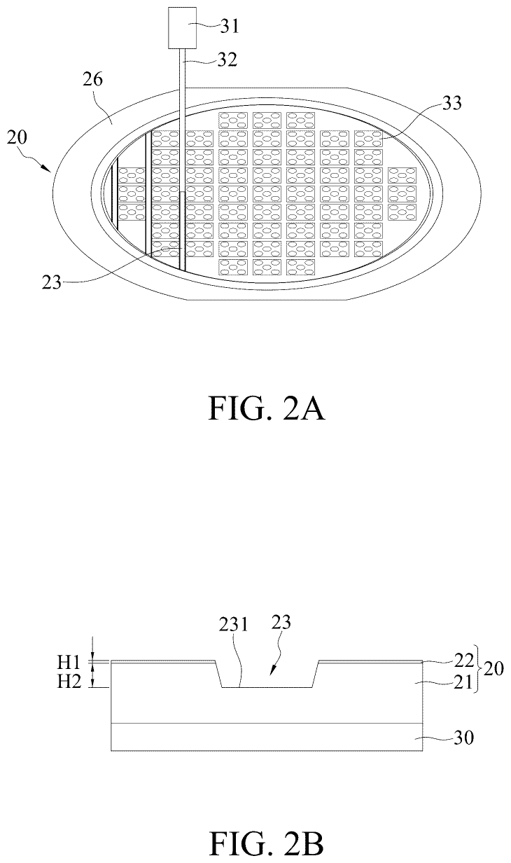

FIG. 1A and FIG. 1B are respectively a top view and a cross-sectional view of a wafer 20 before dicing according to an embodiment of the present disclosure. FIGS. 2A, 3A, 4A and 5A are top views of the wafer 20 during dicing, and FIGS. 2B, 3B, 4B and 5B are cross-sectional views of the wafer 20 during dicing. A wafer dicing method of the present disclosure will be described below with reference to the foregoing drawings.

First, as shown in FIG. 1A and FIG. 1B, a wafer 20 is provided. The wafer 20 is placed on a carrier 30. For example, the carrier 30 may be a dicing tape. A plurality of electronic elements 33 are formed in the wafer 20. Each of the electronic elements 33 may include an active element and/or a passive element, and the active element may be a semiconductor circuit or a semiconductor device, and the passive element may be a resistor, a capacitor, or an inductor. In addition, the wafer 20 includes a wafer body 21 and a passivation layer 22 formed on the wafer body 21.

As shown in FIG. 2A and FIG. 2B, a laser beam 32 emitted by a laser device 31 is used to perform a first dicing on the wafer 20 to form a dicing lane 23. The dicing lane 23 has a bottom surface 231. This first dicing can avoid the wafer 20 from being broken due to stress concentration when the wafer 20 is finally cut off.

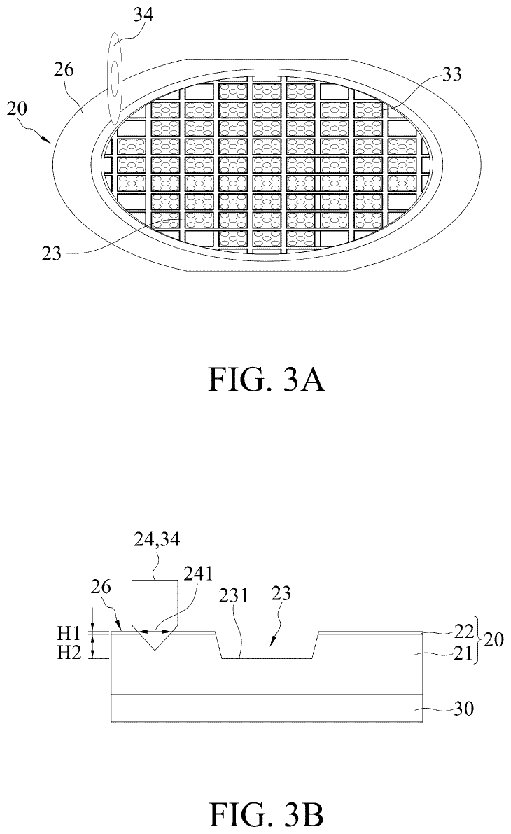

As shown in FIG. 3A and FIG. 3B, a second dicing is performed on the wafer 20 by using a bevel knife 34 of a dicing machine at a position 24 in an inactive area 26 of the edge of the wafer 20. Before the second dicing, the bevel knife 34 is first raised to a height of H1+H2 to compensate for a thickness difference between the position 24 of the wafer 20 in the inactive area 26 and a position 25 of the dicing lane 23, wherein H1 is the thickness of the passivation layer 22, and H2 is a dicing depth of the laser beam 32, that is, the depth of the dicing lane 23. For example, H1 can be 6 microns and H2 can be 14 microns. After the second dicing, a wafer cut width 241 of the second dicing on the wafer 20 can be determined via the feedback of the dicing machine. In detail, the wafer cut width 241 is the width of the dicing formed by the bevel knife 34 at the position 24 on the surface of the passivation layer 22.

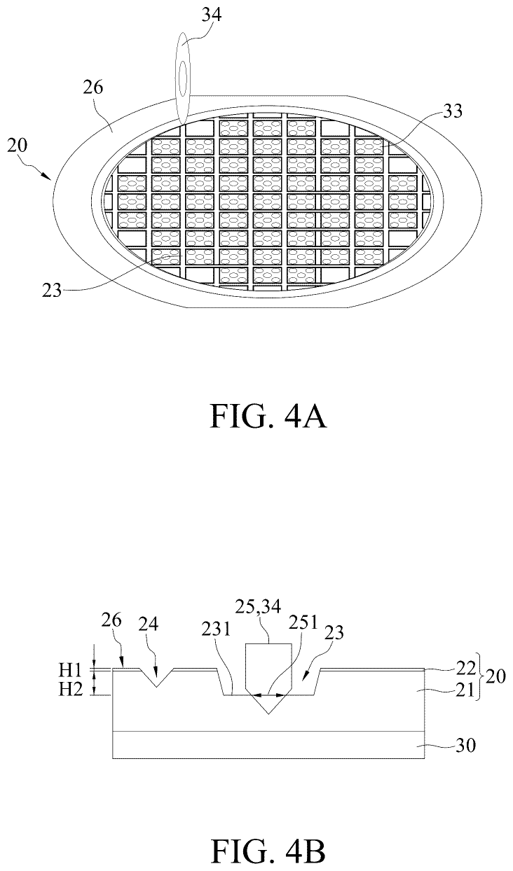

As shown in FIG. 4A and FIG. 4B, the bevel knife 34 of the dicing machine is used to perform a third dicing on the wafer 20 at the position 25 on the bottom surface 231 of the dicing lane 23. This third dicing can also prevent the wafer 20 from being broken due to stress concentration when the wafer 20 is finally cut off. During the third dicing, the wafer cut width 241 of the second dicing is used to activate a Z-axis compensation mechanism of the dicing machine, so that the bevel knife 34 accurately cuts to a predetermined wafer cut width 251, wherein the wafer cut width 251 is the width of the cutting formed by the bevel knife 34 at the position 25 on the bottom surface 231 of the dicing lane 23. The aforementioned Z axis is parallel to the up and down directions in FIGS. 1B, 2B, 3B, 4B and 5B, and perpendicular to the surface of the wafer 20 in FIGS. 1A, 2A, 3A, 4A and 5A.

In one embodiment, the wafer cut width 251 of the third dicing is equal to the wafer cut width 241 of the second dicing.

In one embodiment, a blade of the bevel knife 34 has a bevel angle of 63°.

As shown in FIGS. 2B, 3B and 4B, the first dicing, the second dicing and the third dicing only partially penetrate the thickness of the wafer 20. In other words, the first dicing, the second dicing and the third dicing do not cut off the wafer 20.

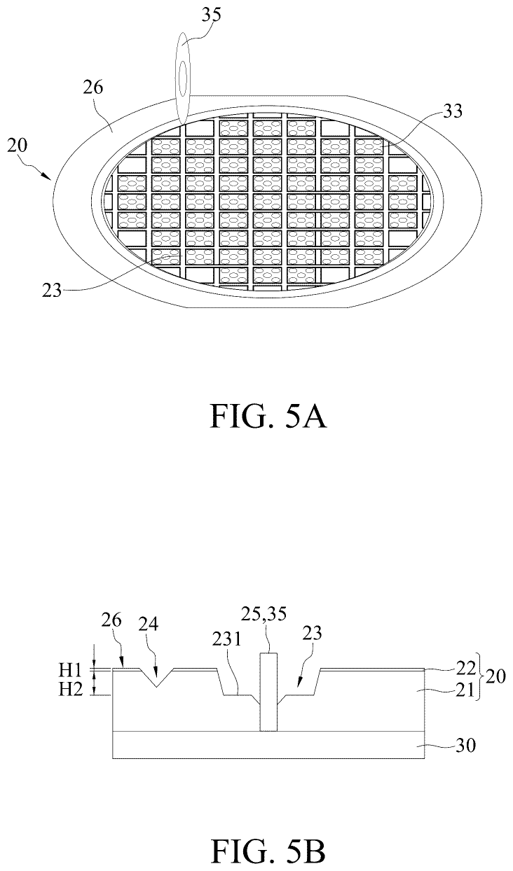

As shown in FIG. 5A and FIG. 5B, a right-angle knife 35 of the dicing machine is used to perform a fourth dicing on the wafer 20 at the position 25 of the third dicing to dice the wafer 20.

As shown in FIGS. 2A, 3A, 4A and 5A, the above-mentioned first dicing to fourth dicing can be performed on the wafer 20 and between the electronic elements 33 to separate the plurality of electronic elements 33 from the wafer 20, and then perform the packaging process of each electronic element 33.

The wafer cut width control of the bevel knife limits the width of the laser beam dicing lane to be greater than 180 microns, and the wafer cut width control falls within 100±20 microns. If it is necessary to use a bevel knife in the smaller 120-micron dicing lane, the control specifications of the wafer cut width will inevitably be more stringent. According to the analysis of simulation results, the wafer cut width needs to be controlled at 90±10 microns to maintain the stress relief effect. However, the bevel knife is greatly affected by the thickness of the wafer and the depth of the dicing lane during laser grooving.

Correspondingly, in the present disclosure, the dicing knife is first raised and cut on the inactive area of the edge of the wafer to eliminate the thickness difference between the pre-dicing position and the third dicing position. Subsequently, the pre-dicing cut width is used to activate the Z-axis compensation mechanism of the dicing machine, so that the knife width can be accurately controlled by the knife axis when dicing the actual object. Through precise control of the wafer cut width, the bevel knife can be used in dicing lanes that are only larger than 120 microns, thereby increasing the applicable dicing lane width range of the bevel knife, so as to solve the conventional problem of the wafer cut width being difficult to control due to the continuous shrinking of the dicing lane width, and to overcome the problem of wafer cut width errors caused by various variations.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A wafer dicing method, comprising:
using a laser beam to perform a first dicing on a wafer to form a dicing lane on the wafer;
using a bevel knife of a dicing machine to perform a second dicing in an inactive area of the wafer, wherein, before the second dicing, the bevel knife is raised to a preset height to compensate for a thickness difference of the wafer in the inactive area and the dicing lane;
obtaining a wafer cut width of the second dicing via a feedback of the dicing machine; and
using the bevel knife to perform a third dicing on a bottom surface of the dicing lane, wherein, during the third dicing, the wafer cut width of the second dicing is used to activate a compensation mechanism of the dicing machine, so that the bevel knife cuts to a predetermined wafer cut width.

2. The wafer dicing method of claim 1, wherein the wafer includes a wafer body and a passivation layer formed on the wafer body.

3. The wafer dicing method of claim 1, wherein a blade of the bevel knife has a bevel angle of 63°.

4. The wafer dicing method of claim 1, wherein the inactive area is located at an edge of the wafer.

5. The wafer dicing method of claim 1, wherein the preset height is equal to a thickness of the passivation layer of the wafer plus a depth of the dicing lane.

6. The wafer dicing method of claim 1, wherein a wafer cut width of the third dicing is equal to the wafer cut width of the second dicing.

7. The wafer dicing method of claim 1, wherein the first dicing, the second dicing and the third dicing do not cut off the wafer.

8. The wafer dicing method of claim 1, further comprising:
using a right-angle knife of the dicing machine to perform a fourth dicing at a position of the third dicing to cut off the wafer.

9. The wafer dicing method of claim 8, wherein a plurality of electronic elements are formed in the wafer, and the wafer dicing method further comprises:
performing the first dicing, the second dicing, the third dicing and the fourth dicing between the electronic elements to separate the plurality of electronic elements from the wafer.

10. The wafer dicing method of claim 9, wherein each of the electronic elements includes an active element and/or a passive element.
